(19) United States
(12) Patent Application Publication
(10) Pub. No.: US 2011/0012147 A1
(43) Pub. Date: Jan. 20, 2011

(54) WAVELENGTH-CONVERTED SEMICONDUCTOR LIGHT EMITTING DEVICE INCLUDING A FILTER AND A SCATTERING STRUCTURE

(75) Inventors: Serge J. Bierhuizen, Santa Rosa, CA (US); Michael R. Krames, Los Altos, CA (US)

Correspondence Address: PHILIPS INTELLECTUAL PROPERTY & STANDARDS, P.O. BOX 3001, BRIARCLIFF MANOR, NY, 10510, US

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/503,506

(22) Filed: Jul. 15, 2009

(51) Int. Cl. H01L 33/00

(52) U.S. Cl. 257/98; 257/E33.067; 257/E33.061

(57) ABSTRACT

A semiconductor structure comprises a light emitting layer disposed between an n-type region and a p-type region. A wavelength converting material is disposed over the semiconductor structure. The wavelength converting material is configured to absorb light emitted by the semiconductor structure and emit light of a different wavelength. A filter configured to reflect blue ambient light is disposed over the wavelength converting material. A scattering structure is disposed over the wavelength converting layer. The scattering structure is configured to scatter light. In some embodiments, the scattering structure is a transparent material having a rough surface, containing non-wavelength-converting particles that appear substantially white in ambient light, or including both a rough surface and white particles.

### FIELD OF INVENTION

The present invention relates to a wavelength-converted semiconductor light emitting devices.

### BACKGROUND

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, composite, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions. III-nitride devices are often formed as inverted or flip chip devices, where both the n- and p-contacts formed on the same side of the semiconductor structure, and light is extracted from the side of the semiconductor structure opposite the contacts.

High power LEDs are now commonly used as flashes in small cameras, including cell phone cameras. The LEDs emit white light. Such LEDs used as flashes are typically one or more GaN LED dies that emit blue light covered by a layer of yttrium aluminum oxide garnet (YAG) phosphor that emits a yellow-green light when energized by the blue light. The combination of the blue light leaking through the YAG phosphor and the yellow-green light appears white.

The YAG phosphor coating on the LED appears yellow-green under white ambient light when the LED is off. Such a yellow-green color is generally not attractive and typically does not match the appearance of the camera. It is desirable to eliminate the yellow-green color of the flash in its off state.

US 2009/0057699 describes one technique for reducing the yellow-green off-state appearance of an LED, illustrated in FIG. 1. The LED 10 includes an n-layer 12, an active layer 14, and a p-layer 16. N— and p-electrodes connect to the n- and p-layers 12 and 16. The semiconductor LED is mounted on a submount 22 as a flip chip. The submount electrodes are electrically connected by vias to cathode and anode pads 24 on the bottom of the submount so the submount can be surface mounted to metal pads on a printed circuit board, which typically forms part of the flash module for a camera. A phosphor layer 30 is formed over the top of the LED for wavelength-converting the blue light emitted from the active layer 14.

A silicone encapsulant 32 is formed over the LED structure to protect the LED and to increase light extraction. TiO₂ particles 34 are mixed with the silicone encapsulant 32 before encapsulating the LED. The optimum quantity of TiO₂ may vary anywhere between 1-10% of the weight of the silicone depending on the characteristics of the LED structure. The encapsulant containing the TiO₂ may be spun on or molded directly over the LED and phosphor. If it is desired to use the encapsulant as a lens, the encapsulant may be shaped using a mold. The average TiO₂ particle size is 0.25 micron, and the particles are randomly shaped. The thickness of the silicone is about 100 microns.

### SUMMARY

It is an object of the present invention to form a wavelength-converted semiconductor light emitting device with high efficiency and suitably white off-state appearance.

Embodiments of the invention include a semiconductor structure comprising a light emitting layer disposed between an n-type region and a p-type region. A wavelength converting material is disposed over the semiconductor structure. The wavelength converting material is configured to absorb light emitted by the semiconductor structure and emit light of a different wavelength. A filter configured to reflect blue ambient light is disposed over the wavelength converting material. A scattering structure is disposed over the wavelength converting layer. The scattering structure is configured to scatter light. In some embodiments, the scattering structure is a transparent material having a rough surface, containing non-wavelength-converting particles that appear substantially white in ambient light, or including both a rough surface and white particles.

### BRIEF DESCRIPTION OF THE DRAWINGS

FIG. 1 illustrates an LED coated with a phosphor and white-colored non-phosphor particles disposed in a transparent encapsulant.

FIG. 2 illustrates an LED with a wavelength converting layer, a dichroic layer, and a scattering structure, according to embodiments of the invention.

FIG. 3 is a plot of transmittance as a function of wavelength for various angles of incidence, for a dichroic filter.

### DETAILED DESCRIPTION

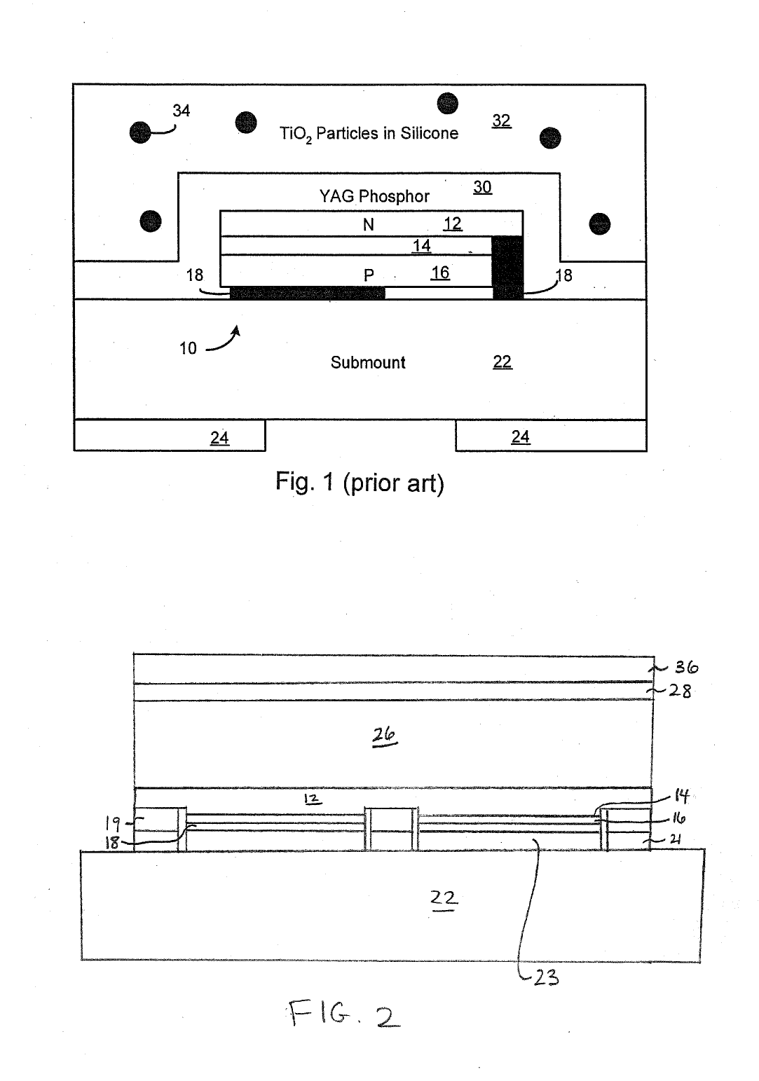

In applications where the color of the LED in the off state must be extremely white, increasing the thickness or concentration of white-colored particles in the device illustrated in FIG. 1 may improve the off-state white appearance of the LED, but may reduce the efficiency of the device.

A dichroic filter may be used to reflect blue light from the environment, such that the light cannot reach and excite the phosphor; however, environmental light reflected by a dichroic filter has an undesirable color variation with viewing angle.

In embodiments of the invention, a dichroic layer is combined with a scattering structure such as a rough surface or a transparent layer including white-colored particles, to preferentially reflect blue light over red and green light. Blue light is efficiently reflected by the dichroic, which improves the off-state appearance of the LED. The scattering structure may provide additional whiteness and may reduce the color variation with view angle caused by the dichroic layer.

FIG. 2 illustrates a device according to embodiments of the invention. A semiconductor light emitting device such as a III-nitride LED is grown over a growth substrate (not shown in FIG. 2) such as sapphire, SiC, or GaN. Generally, an n-type region 12 is grown first, followed by a light emitting or active region 14, followed by a p-type region 16.

N-type region 12 may include multiple layers of different compositions and dopant concentration including, for example, preparation layers such as buffer layers or nucleation layers, which may be n-type or not intentionally doped, release layers designed to facilitate later release of the growth substrate or thinning of the semiconductor structure after substrate removal, and n- or even p-type device layers designed for particular optical or electrical properties desirable for the light emitting region to efficiently emit light.

A light emitting or active region 14 is grown over n-type region 12. Examples of suitable light emitting regions include a single thick or thin light emitting layer, or a multiple quantum well light emitting region including multiple thin or thick quantum well light emitting layers separated by barrier layers. For example, a multiple quantum well light emitting region may include multiple light emitting layers, each with a thickness of 25 Å or less, separated by barriers, each with a thickness of 100 Å or less. In some embodiments, the thickness of each of the light emitting layers in the device is thicker than 50 Å.

A p-type region 16 is grown over light emitting region 14. Like the n-type region, the p-type region may include multiple layers of different composition, thickness, and dopant concentration, including layers that are not intentionally doped, or n-type layers.

One or more portions of the p-type region 16 and light emitting region 14 may be removed to expose a portion of the underlying n-type region 12. Metal electrodes 19 and 18, which may be reflective and which may be, for example, silver, aluminum, or an alloy, are then formed over the surface of the LED to contact the n- and p-type regions. The electrodes may be distributed electrodes to more evenly spread the current. When the diode is forward biased, the active layer 14 emits light whose wavelength is determined by the composition of the active layer. Forming such LEDs is well known. Additional detail of forming LEDs is described in U.S. Pat. No. 6,828,596 to Steigerwald et al. and U.S. Pat. No. 6,876,008 to Bhat et al., both assigned to the present assignee and incorporated herein by reference.

The semiconductor LED is then bonded to a mount 22 as a flip chip. The top surface of mount 22 may contain metal electrodes that are soldered or ultrasonically welded to the electrodes 18 and 19 on the LED via solder, an elemental metal interconnect such as gold, or any other suitable interconnects 21 and 23. Other types of bonding can also be used. Interconnects 21 and 23 may be omitted if the structures on the LED and on the mount can be directly connected.

The mount electrodes may be electrically connected by vias to cathode and anode pads (not shown in FIG. 2) on the bottom of the mount so the mount can be surface mounted to metal pads on a printed circuit board, which typically forms part of the flash module for a camera. Metal traces on the circuit board electrically couple the pads to a power supply. The mount 22 may be formed of any suitable material, such as ceramic, silicon, aluminum, etc. If the mount material is conductive, an insulating layer is formed over the substrate material, and the metal electrode pattern is formed over the insulating layer. The mount 22 acts as a mechanical support, provides an electrical interface between the delicate n and p electrodes on the LED chip and a power supply, and provides heat sinking. Mounts are well known.

After bonding the LED to the mount, the growth substrate may be removed, such as by CMP or laser lift-off, where a laser heats the interface of the semiconductor material and the growth substrate to create a high-pressure gas that pushes the substrate away from the semiconductor material. The semiconductor may be thinned after removing the substrate, for example by photoelectrochemical etching, and the surface of the n-type region may be textured, for example by roughening or etching a pattern such as a photonic crystal, to improve light extraction or scattering. In one embodiment, removal of the growth substrate is performed after an array of LEDs is mounted on a wafer of mounts and prior to the LEDs/submounts being singulated (e.g., by sawing). The final thickness of the semiconductor layers may be about 40 microns. The LED layers plus submount may be about 0.5 mm thick. Processing of the LED semiconductor layers may occur before or after the LED is bonded to the mount 22.

A wavelength converting layer 26 is formed over the top of the LED for wavelength-converting the light emitted from the active layer 14. The wavelength converting layer 26 may be for example, one or more phosphors which are spray deposited, spun-on, thin-film deposited by electrophoresis, preformed as a ceramic plate and affixed to the top of the LED layers, or formed using any other technique. Luminescent ceramics are described in U.S. Pat. No. 7,361,938, which is incorporated herein by reference. The wavelength converting layer 26 may be phosphor particles in a transparent or translucent binder, which may be organic or inorganic, or may be sintered phosphor particles. Though the wavelength converting layer 26 covers only the top surface of the semiconductor structure in the device illustrated in FIG. 2, in some embodiments of the invention, the wavelength converting layer 26 covers the side surfaces of the semiconductor structure as well. In some embodiments the sides of wavelength converting layer 26 are coated with a reflective material such as silver, or a transparent material with a high concentration of reflective particles, such as TiO₂ particles at a concentration greater than 10% disposed in, for example, silicone such as Silres available from Wacker Chemie AG, or a sol gel solution. The reflective material disposed on the sides of wavelength converting layer 26 prevents or reduces the amount of light escaping wavelength converting layer 26 through the sides.

In some embodiments, the light emitted by the wavelength converting layer 26, when mixed with blue light emitted by the active region 14, creates white light or another desired color, such as green or amber. In one example, the wavelength converting layer 26 includes a yttrium aluminum garnet (YAG) phosphor that produces yellow light (Y+B=white). The wavelength converting layer 26 may be any other phosphor or combination of phosphors, such as a red phosphor and a green phosphor (R+G+B=white), to create white light. The thickness of the wavelength converting layer 26 may be, for example, between 20 and 200 microns.

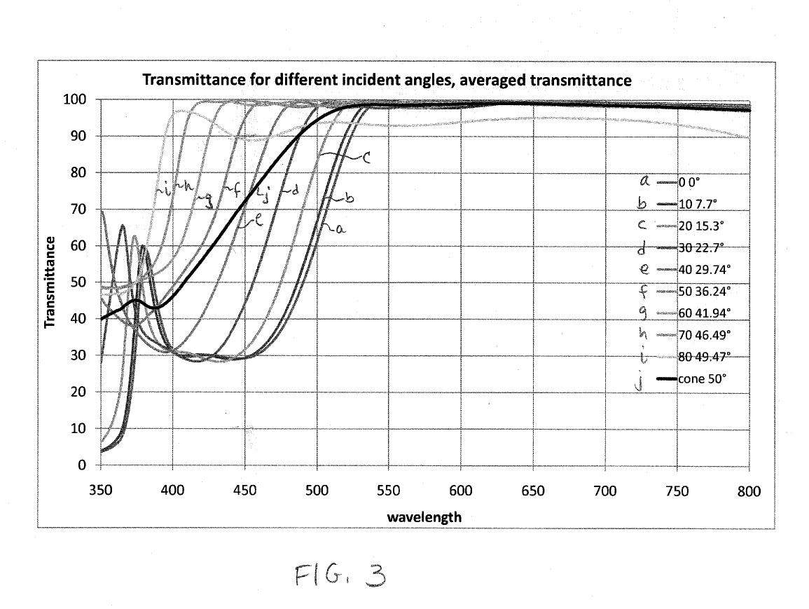

A dichroic filter 28 is formed over wavelength converting layer 26. Dichroic filter 28 is selected to reflect at least a portion of the blue ambient light incident on the filter. One example of a dichroic filter is illustrated in FIG. 3, which is a plot of transmittance as a function of wavelength for light of different incident angles. At a wavelength of 450 nm, between 25% and 100% of the light is transmitted for the filter illustrated in FIG. 3, depending on the incidence angle. In some embodiments, the dichroic filter is configured such that at a peak emission wavelength of the active layer 14, averaged over all incidence angles, between 10% and 90% of light incident on the dichroic filter 28 is transmitted. Suitable dichroic filters are well known and available from, for example, Ocean Optics, 830 Douglas Ave. Dunedin, Fla. 34698.

With a YAG phosphor (i.e., Ce:YAG), the color temperature of the white light depends largely on the Ce doping in the phosphor as well as the thickness of the wavelength converting layer 26. In some embodiments, the inclusion of a dichroic filter may permit use of a lower cerium concentration in a YAG phosphor, or a thinner wavelength converting layer. In addition to ambient blue light in the off-state, dichroic filter 28 also reflects blue light emitted by the active region in the on-state. The light is reflected back into the wavelength converting layer 26, where it has another opportunity to be wavelength converted. Since a portion of the light makes multiple passes through the wavelength converting material, the same amount of wavelength converted light may be achieved with a lower dopant concentration, or a thinner wavelength converting layer, as compared to a device without a dichroic filter. Reducing the cerium concentration in a YAG phosphor, or the thickness of the wavelength converting layer, may also improve the off-state white appearance of the device, by reducing the amount of yellow light generated by the blue portion of the ambient light with the wavelength converting layer in the off-state.

A scattering structure 36 is formed over dichroic filter 28. The scattering structure may introduce scattering, which reduces or minimizes color-over-angle variation in the off-state caused by dichroic filter 28. In some embodiments, the scattering structure is configured such that at least 10% of a quantity of collimated light incident on the scattering structure at 0° relative to a normal to a top surface of the device is scattered into angles between 5° and 85° relative to a normal to a top surface of the device.

In some embodiments, scattering structure 36 is a transparent material with a roughened top surface. In some embodiments, the roughened top surface has a roughness parameter Ra, which is an arithmetic average of the roughness profile, of at least 40 521 rms.

In some embodiments, scattering structure 36 is a layer of white-colored particles disposed in a transparent material. The white particles may be, for example, TiOₓ, TiO₂, AlₓO_{y}, Al₂O₃, ZrOₓ, ZrO₂, or any other suitable particle, and may be small, for example with an average particle diameter less than one micron in some embodiments, and between 0.05 and 0.8 microns in some embodiments. The white particles may be disposed in, for example, a transparent material such as silicone, silres, epoxy, or a sol gel. The total thickness of a white-particle layer may be, for example, between 0.5 and 250 microns. The concentration of particles may be, for example, between 1% and 7% of the weight of the transparent material. If the transparent material is thin, the concentration of particles may be greater than 7%. In some embodiments, the top surface of a white-colored particle layer is roughened.

In some embodiments, the scattering structure 36 may be spaced apart from the dichroic filter 28.

The dichroic layer 28 and white particle layer 36 may preferentially reflect blue light more than green or red light, resulting in a better off-state white appearance of the device without significantly reducing the efficiency of the device in the on-state.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A device comprising:
a semiconductor structure comprising a light emitting layer disposed between an n-type region and a p-type region;
a wavelength converting material disposed over the semiconductor structure, wherein the wavelength converting material is configured to absorb light emitted by the semiconductor structure and emit light of a different wavelength;
a filter disposed over the wavelength converting material, wherein the filter is configured to reflect at least a portion of blue ambient light; and
a scattering structure disposed over the wavelength converting layer, wherein the scattering structure is configured to scatter light.

2. The device of claim 1 wherein the scattering structure is a transparent material containing non-wavelength-converting particles that appear substantially white in ambient light.

3. The device of claim 2 wherein the particles comprise TiO₂.

4. The device of claim 2 wherein the particles comprise one of TiOₓ, AlₓO_{y}, Al₂O₃, ZrOₓ, and ZrO₂.

5. The device of claim 2 wherein the transparent material comprises silicone.

6. The device of claim 2 wherein the transparent material comprises one of epoxy, silres, and sol gel.

7. The device of claim 2 wherein the particles have an average diameter less than one micron.

8. The device of claim 2 wherein the particles comprise between 1% and 7% of the encapsulant.

9. The device of claim 1 wherein the scattering structure is a transparent material with a rough top surface.

10. The device of claim 9 wherein a top surface of the scattering structure has a roughness parameter Ra of at least 40 Å rms.

11. The device of claim 1 wherein the light emitting layer is a III-nitride layer configured to emit blue light when forward biased.

12. The device of claim 1 wherein the wavelength converting material is a ceramic phosphor.

13. The device of claim 1 wherein the wavelength converting material is configured to emit yellow light.

14. The device of claim 1 wherein the filter is a dichroic filter.

15. The device of claim 1 wherein the scattering structure is configured such that at least 10% of a quantity of collimated light incident on the scattering structure at 0° relative to a normal to a top surface of the filter is scattered into angles between 5° and 85° relative to a normal to a top surface of the filter.
